(19) United States
(12) Patent Application Publication
(10) Pub. No.: US 2008/0213676 A1
(43) Pub. Date: Sep. 4, 2008

(54) PHASE SHIFT MASK FOR AVOIDING PHASE CONFLICT

(76) Inventors: Chih-Li Chen, Taipei County (TW); Tsan Lu, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 11/854,510

(22) Filed: Sep. 12, 2007

(30) Foreign Application Priority Data
Mar. 3, 2007 (TW) 096107387

(51) Int. Cl. G03F 1/00

(52) U.S. Cl. 430/5

(57) ABSTRACT

A phase shift mask comprises a glass substrate with a surface and a metal layer. The glass substrate comprises a first phase section, a second phase section and a border section. The metal layer is covered on the glass substrate and defining a pattern comprising a plurality of parallel lines, the first phase section and the second phase section. The terminal of at least one of the lines is not rectangular and a distance between the tips of the lines in the first phase section are defined to be not less than the width of the first phase section.

### BACKGROUND OF THE INVENTION

1. Field of the Invention

The present invention relates to a phase shift mask. More particularly, the present invention relates to a phase shift mask for avoiding the phase conflict.

2. Description of the Prior Art

In integrated circuit making processes, a lithographic process has become a mandatory technique. In a lithographic process, a designed pattern, such as a circuit pattern, or a contact hole pattern is created on one or several photo masks. Then the pattern on the photo mask is transferred by light exposure, with a stepper and scanner, into a photoresist layer on a semiconductor wafer. Only by using a lithographic process can a wafer producer precisely and clearly transfer a complicated circuit pattern onto a semiconductor wafer.

It is an important issue to enhance the resolution of the lithographic process due to the reducing device sizes of the semiconductor industry. Theoretically speaking, short wavelengths of light are desirable as using shorter wavelengths of light to expose a photoresist layer will proportionally improve the resolution. This method, though it seems simple, is not feasible. First, light sources for providing short wavelengths of light are not accessible. Secondly, the damage of equipment is very considerable when short wavelengths of light is used to expose a photoresist layer, leading to a shorted equipment lifetime. The cost is thus raised, which makes products not competitive. Due to the conflicts between theory and practice used in manufacturing, the manufacturers are all devoted to various types of research so as to get over this problem.

In the current Resolution Enhancement Technology (RET), phase shift masks are always one of the most critical tools to enhance the resolution. Generally speaking, because the phase of the light is not shifted when the light passes through the traditional masks, some light forms constructive interference on the surface of the wafer and causes worse resolution when some silent patterns are exposed due to the interference.

The phase shift masks are the masks with additional phase shifters selectively between the metal Cr line patterns. When the light passes through the phase shifter of the phase shift masks, the phase of the electric field of the light is shifted exactly 180°, so the phase difference between the incident light and the shifted light is exactly half-wavelength and destructive interference is therefore formed on the wafer. The interference effect of the diffraction is resolved by the destructive interference and the resolution of the border of the metal lines is greatly enhanced.

However the RET of the phase shift masks still have drawbacks. For example, the distance between the metal lines on the phase shift masks shortens due to the reducing device sizes. FIG. 1 illustrates the design of the metal lines on a phase shift mask. The phase shift mask 11 includes a glass substrate 12 and metal lines 13. When the pitch “a” between the metal lines 13 on the phase shift mask 11 is too short, the interconnect 19 causes defects and damages the quality of the patterns occurs on the terminal section of the metal lines 13 near the border 17 of the phase inversion due to the phase conflict.

### SUMMARY OF THE INVENTION

The present invention provides a phase shift mask, which avoids the defects of the lithographic patterns due to phase shift conflict, to ensure the resolution and the quality of the lithographic patterns and solves the problems in the prior art.

The phase shift mask of the present invention includes a glass substrate with a surface and a metal layer on the glass substrate. The glass substrate comprises a first phase section, a second phase section and a border section. The metal layer is covered on the glass substrate and defining a pattern comprising a plurality of parallel lines, the first phase section and the second phase section. The terminal of at least one of the lines is not rectangular, preferably triangular or trapezoidal, and a distance between the tips of the lines in the first phase section are defined to be not less than the width of the first phase section.

The present invention provides another phase shift mask, which includes a glass substrate, a plurality of parallel metal lines including a first metal line, a third metal line and a second metal line between the first metal line and the third metal line adjacent to each other on the glass substrate, a first phase section which is between the first metal line and the second metal line and includes a tapered part between the corresponding terminal of the first metal line and the second metal line, a second phase section between the second metal line and the third metal line, and a border section adjacent to the taper part of the first phase section.

Because the first phase section which is between the terminals of the metal lines and adjacent to the border section includes a tapered, non-rectangular part, the terminal distance of the metal lines, i.e. the border of the phase inversion, is substantially widened. Accordingly, even if the pitch of the metal lines on the phase shift mask shortens, the phase conflict on the border of the phase inversion and the undesired interconnect can be avoided. The resolution and the quality of the lithographic patterns formed by the masks are ensured and the problems in the prior art are solved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates the design of the metal lines on a conventional phase shift mask.

FIG. 2 illustrates a preferred embodiment of the phase shift mask of the present invention.

FIG. 3 illustrates another preferred embodiment of the phase shift mask of the present invention.

### DETAILED DESCRIPTION

The present invention provides a novel phase shift mask, which avoids the defects of the lithographic patterns due to phase conflict, and ensures the resolution and the quality of the lithographic patterns formed by the mask and solves the problems caused by the extremely small pitch of the metal lines. Because the first phase section which is between the terminals of the metal lines and adjacent to the border section includes a tapered, non-rectangular part, the border of the phase inversion is substantially widened. Accordingly, even if the pitch of the metal lines on the phase shift mask shortens, the phase conflict on the border of the phase inversion and the undesired interconnect can be avoided.

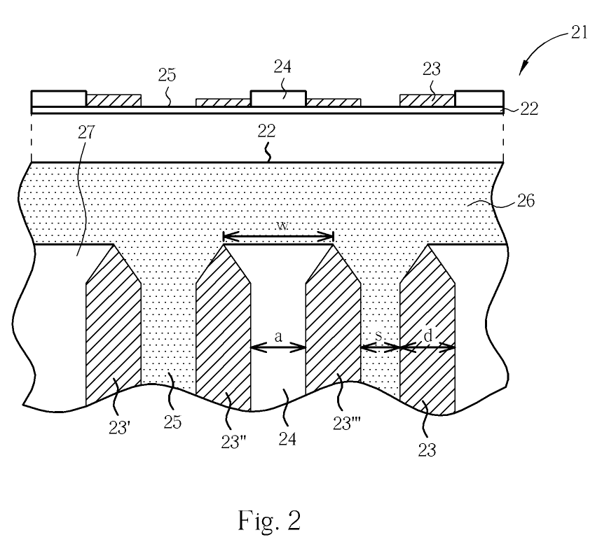

FIG. 2 Illustrates a preferred embodiment of the phase shift mask of the present invention with the top being the side view and the bottom being the top view. The phase shift mask 21 includes a glass substrate 22 and a metal layer 23 covered on the surface of the glass substrate 22. Because the glass substrate 22 is required to have high rate of transmission to the light source, the glass substrate 22 generally speaking is made of quartz. The metal layer 23 is used to block the light so as to form the predetermined pattern on the photoresist, but is also easily etched and patterned. The metal layer 23 usually includes Cr, or other suitable material.

There are a first phase section 24, a second phase section 25 and a border section 26 on the surface of the glass substrate 22. A pattern, which may include a plurality of parallel lines, the first phase section 24 and the second phase section 25, is defined through the patterned metal layer 23. It is to be noticed that the first phase section 24 and the second phase section 25 are arbitrary and not limited to what is illustrated in FIG. 2.

To be functional, at lease one of the first phase section 24, the second phase section 25 and the border section 26 is processed to be able to perform “phase shift.” For example, the processed first phase section 24 is able to render a predetermined electromagnetic wave have a phase difference of 180° after passing through the first phase section and the second phase section or passing through the first phase section and the border section.

There are many known processing methods. For example, the relative thickness of a certain section of a substrate is altered such as forming a trench, or a phase shift material is selectively added so that the phase of the electric field of a light source is shifted exactly 180° after passing through the phase shift layer of the phase shift mask. Because the phase difference between the incident light and the shifted light is exactly a half wavelength, destructive interference is therefore formed on the wafer. The interference effect of the diffraction is resolved by the advantageous effect and the resolution on the border of the metal lines is greatly enhanced. The suitable light source depends on the resolution of the patterns.

The pattern usually includes a plurality of parallel lines, such as line 23′, line 23″ and line 23′″. The alternate arrangement of the lines defines the line width “d” of the metal line, the width “a” of the first phase section and the width s of the second phase section. The line width d of the metal line, the width a of the first phase section and the width s of the second phase section may be equal or different. For example, the line width d of the metal line, the width a of the first phase section and the width s of the second phase section are equal so that the width of the first phase section and the lines are equal and the pitch of the lines are equal, too. The line width d of the metal line, the width a of the first phase section and the width s of the second phase section depend on the actual size of the elements on the semiconductor substrate.

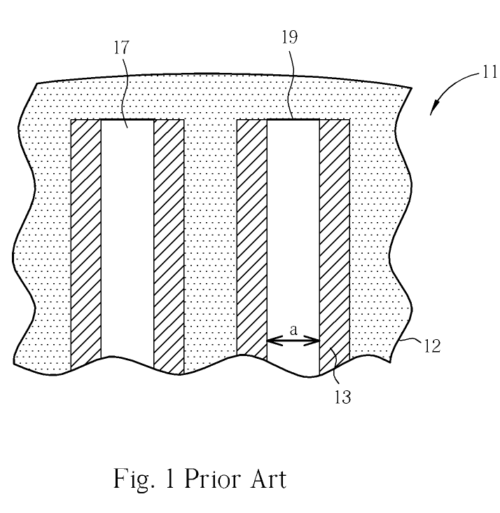

On traditional masks, the terminals of the lines are rectangular, as shown in FIG. 1, so that the pitch s is constant all the way. Once the pitch a of the metal lines 13 on the phase shift mask 11 is too narrow, undesired interconnect 19 occurs on the terminals of metal lines 13 at the border 17 of the phase inversion due to phase conflict. This will cause defects and damage the quality of the formed patterns.

However, the phase shift mask of the present invention is characterized in that at least one of the terminals 27 of the metal lines such as line 23′, the line 23″ and the line 23′″ are non-rectangular, such as triangular or trapezoidal. For example, an isosceles triangle is shown in FIG. 2. In such a way, the distance w between the tips of the metal lines, the width on the border of the phase shift inversion, is widened. For example, the distance w of the tips of the metal lines on the first phase section 24 is not less than the width a, preferably not less than twice of the width a, of the first phase section.

Accordingly, even if the pitch of the metal lines on the phase shift mask shortens, the distance w is still wide enough to avoid the phase conflict on the border of the phase inversion and the undesired interconnect. The resolution and the quality of the lithographic patterns formed by the masks are ensured and the problems in the prior art are solved.

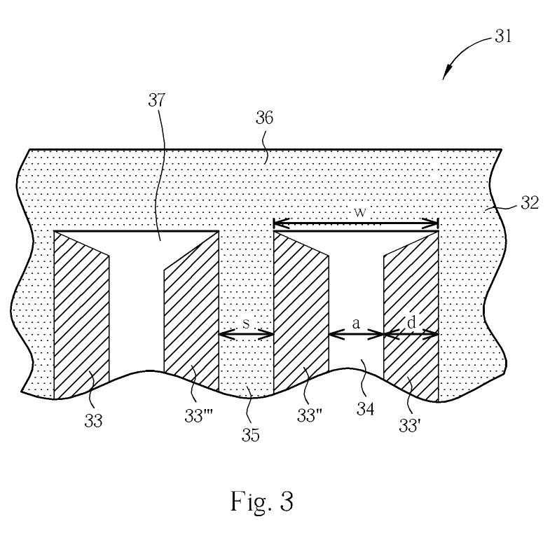

FIG. 3 illustrates another preferred embodiment of the phase shift mask of the present invention. The phase shift mask 31 includes a glass substrate 32, a plurality of parallel metal lines 33 on the surface of the glass substrate 32, a first phase section 34, a second phase section 35 and a border section 36. Because the glass substrate 32 is required to have high rate of transmission to the light source, the glass substrate 32 generally speaking is made of quartz. A plurality of parallel metal lines 33 are used to block the light so as to form the predetermined pattern on the photoresist but also easily to be etched and patterned. The metal lines 33 usually include Cr, or other suitable materials.

Metal lines 33 include the first metal line 33′, the second metal line 33″ and the third metal line 33′″ adjacent to each other. The alternate arrangement of the metal lines 33 defines the line width “d” of the metal line, the width “a” of the first phase section and the width “s” of the second phase section. The line width d of the metal line, the width a of the first phase section and the width s of the second phase section may be equal or different. For example, the line width d of the metal line, the width a of the first phase section and the width s of the second phase section are equal so that the width of the first phase section and the metal lines are equal and the pitch of the parallel lines are equal, too. The line width d of the metal line, the width a of the first phase section and the width s of the second phase section depend on the actual size of the elements on the semiconductor substrate. There is a first phase section 34 between the first metal line 33′ and the second metal line 33″ on the glass substrate 32 and the first phase section 34 further includes a tapered part 37 between the corresponding terminals of the first metal line 33′ and the second metal line 33″. In addition, there is a second phase section 35 between the second metal line 33″ and the third metal line 33′″ on the glass substrate 32 and a border section 36 adjacent to the tapered part 37, i.e. on the border of the phase inversion. Each phase section is defined through the metal lines 33. It is to be noticed that the first phase section 34 and the second phase section 35 are arbitrary and not limited to what is illustrated in FIG. 3.

To be functional, at lease one of the first phase section 34, the second phase section 35 and the border section 36 is processed to be able to perform “phase shift.” For example, the processed first phase section 34 is able to render a predetermined electromagnetic wave have a phase difference of 180° after passing through the first phase section 34 and the second phase section 35 or passing through the first phase section 34 and the border section 36.

On traditional masks, the terminals of the metal lines are rectangular, as shown in FIG. 1, so that the pitch s is constant all the way. Once the pitch a of the metal lines 13 on the phase shift mask 11 is too narrow, undesired interconnect 19 occurs on the terminals of metal lines 13 at the border 17 of the phase inversion due to phase conflict. This will cause defects and damage the quality of the formed patterns.

However, the first phase section 34 of the phase shift mask in the preferred embodiment includes a tapered part 37 so that the distance w between the tips of metal lines, i.e. the width of the border of the phase inversion, is much wider than the width a of the first phase section. Preferably, the distance w of the tips of the metal lines is not less than twice of the width a of the first phase section.

Accordingly, even if the pitch of the metal lines on the phase shift mask shortens, the distance w is still wide enough to avoid the phase conflict on the border of the phase inversion and the undesired interconnect. Thus, the resolution and the quality of the lithographic patterns formed by the masks are ensured and the problems in the prior art are solved.

Those skilled in the art will readily observe that numerous modifications and alterations of the device and method may be made while retaining the teachings of the invention.

What is claimed is:

1. A phase shift mask, comprising:
a glass substrate with a surface, said glass substrate comprising a first phase section, a second phase section and a border section; and
a metal layer covered on said glass substrate and defining a pattern comprising a plurality of parallel lines, the first phase section and the second phase section, wherein the terminal of at least one of the lines is not rectangular and a distance between the tips of the lines in the first phase section is defined to be not less than the width of the first phase section.

2. The phase shift mask of claim 1, wherein said metal layer comprises Cr.

3. The phase shift mask of claim 1, wherein a predetermined wave having passed through said first phase section and second phase section has a phase difference of 180°.

4. The phase shift mask of claim 1, wherein the terminal of said lines is triangular.

5. The phase shift mask of claim 3, wherein said predetermined wave having passed through said first phase section and said border section has a phase difference of 180°.

6. A phase shift mask, comprising:
a glass substrate;
a plurality of parallel metal lines including a first metal line, a second metal line and a third metal line adjacent to each other on said glass substrate, wherein said second metal line is between said first metal line and said third metal line;
a first phase section between said first metal line and said second metal line, wherein said first phase section comprises a tapered part between corresponding terminals of said first metal line and said second metal line;
a second phase section between said second metal line and said third metal line; and
a border section adjacent to said taper part of said first phase section.

7. The phase shift mask of claim 6, wherein said metal lines comprise Cr.

8. The phase shift mask of claim 6, wherein a predetermined wave having passed through said first phase section and said second phase section has a phase difference of 180°.

9. The phase shift mask of claim 8, wherein said predetermined wave having passed through said first phase section and said border section has a phase difference of 180°.
